(19) United States
(12) Patent Application Publication
(10) Pub. No.: US 2015/0014793 A1
(43) Pub. Date: Jan. 15, 2015

(54) PRESSURE SENSOR HAVING DOWN-SET FLAG

(71) Applicants: Kai Yun Yow, Petaling Jaya (MY); Poh Leng Eu, Petaling Jaya (MY)

(72) Inventors: Kai Yun Yow, Petaling Jaya (MY); Poh Leng Eu, Petaling Jaya (MY)

(21) Appl. No.: 13/941,556

(22) Filed: Jul. 15, 2013

(51) Int. Cl. H01L 25/00; H01L 25/16; H01L 29/84

(52) U.S. Cl. CPC H01L 25/50; H01L 29/84; H01L 25/16
USPC 257/415; 438/51

(57) ABSTRACT

A semiconductor sensor device has a lead frame having an outer frame with wire bond pads and a die pad to which a pressure sensor die is mounted. The die pad is vertically offset from the outer frame and wire bond pads by tie bars that have down set structures. The die pad has an opening, and the sensor die is mounted on the first die attach pad such that the opening provides access to an active region of the sensor die. Pressure sensitive gel is applied over the active region of the sensor die. Molding compound covers the sensor die and gel. The molding compound has a hole corresponding to the opening in the die pad to enable ambient atmospheric pressure outside of the sensor device to reach the sensor die via the pressure sensitive gel.

### BACKGROUND OF THE INVENTION

The present invention relates generally to semiconductor sensor devices, and more particularly to semiconductor pressure sensors.

Semiconductor sensor devices such as pressure sensors are well known. Such devices use semiconductor pressure sensing dies. These dies are susceptible to mechanical damage during packaging and environmental damage when in use, and thus they must be carefully packaged. Further, pressure sensing dies, such as piezo resistive transducers (PRTs) and parameterized layout cells (P-cells), do not allow full encapsulation because that would impede their functionality.

FIGS. 1(A), (B) and (C) shows a conventional semiconductor sensor device 100. FIG. 1(A) is a cross-sectional side view of the sensor device 100; FIG. 1(B) is a perspective top view of the sensor device 100 partially assembled; and FIG. 1(C) shows a perspective top view of a lid 104 of the device 100.

The device 100 includes a pressure sensing die (P-cell) 106, acceleration sensing die (G-cell) 108, and micro-control unit (MCU) 110, which are mounted to a lead frame flag 112, electrically connected to package leads 118 with bond wires (not shown), and covered with a pressure sensitive gel 114, which enables the pressure of the ambient atmosphere to reach the pressure sensitive active region on the top side of the P-cell 106 while protecting each of the dies 106, 108, 110 and the bond wires from mechanical damage during packaging and environmental damage (e.g., contamination and/or corrosion) when in use. The entire die/substrate assembly is encased in molding compound 102 and covered with a lid 104, which has a vent hole 116 that exposes the gel-covered P-cell 106 to ambient atmospheric pressure outside the sensor device.

One problem with the design of sensor device 100 is the high manufacturing cost due to the pre-molded package base, the metal lid, and the large volume of pressure sensitive gel. Accordingly, it would be advantageous to have a more-economical way to assemble semiconductor sensor devices.

### BRIEF DESCRIPTION OF THE DRAWINGS

Embodiments of the present disclosure are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 shows a conventional packaged semiconductor sensor device having a metal lid;

FIG. 2 shows a semiconductor sensor device in accordance with an embodiment of the disclosure;

FIGS. 3-8 illustrate an embodiment of a process for assembling the sensor device of FIG. 2;

FIGS. 9 and 10 illustrate alternative techniques for assembling the sensor device of FIG. 2;

FIGS. 11-13 show die/lead frame sub-assemblies for sensor devices according to other embodiments of the present invention; and

FIG. 14 illustrates some additional steps in the assembly process for the sensor device of FIG. 13.

### DETAILED DESCRIPTION OF THE INVENTION

Detailed illustrative embodiments of the present disclosure are disclosed herein. However, specific structural and functional details disclosed herein are merely representative for purposes of describing example embodiments of the present disclosure. Embodiments of the present disclosure may be embodied in many alternative forms and should not be construed as limited to only the embodiments set forth herein. Further, the terminology used herein is for the purpose of describing particular embodiments only and is not intended to be limiting of example embodiments of the disclosure.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment, the present invention provides a method for assembling a semiconductor sensor device, and another embodiment is the resulting semiconductor sensor device. One or more dies including a pressure sensing die are mounted to at least a first die attach pad of a lead frame. The lead frame also has an outer frame with a plurality of attached leads. The first die attach pad is connected to the outer frame by a plurality of tie bars. The lead frame defines a first lateral plane, and the first die attach pad defines a second lateral plane vertically offset from the first lateral plane. The pressure sensing die is mounted to the first die attach pad, which has an opening that provides access to an active region of the die. The one or more dies are electrically connected to corresponding leads of the lead frame with bond wires. The wire bonded dies, the first die attach pad, and the corresponding leads are encapsulated in a molding compound, while preserving access to the active region of the pressure sensing die via the opening in the first die attach pad. Pressure sensitive gel is applied through the opening in the first die attach pad to cover the active region of the pressure sensing die. The sensor device is separated from one or more other adjacent devices, where the multiple leads are detached from the outer frame of the lead frame.

Another embodiment of the present invention is a semiconductor sensor device comprising a first die attach pad having an opening, one or more dies including a pressure sensing die mounted to the first die attach pad, a plurality of leads, bond wires electrically connecting the dies to corresponding ones of the leads, a plurality of tie bars connected to the first die attach pad, pressure sensitive gel covering an active region of the pressure sensing die, and molding compound that encapsulates the first die attach pad, the one or more dies, the leads, the bond wires, and the tie bars. The plurality of leads lie in a first lateral plane, and the first die attach pad lies in a second lateral plane that is vertically offset from the first lateral plane. The opening in the first die attach pad provides access to the active region of the pressure sensing die. There is a hole in the molding compound corresponding to the opening in the first die attach pad, which exposes the gel-covered active region of the pressure sensing die to ambient atmospheric pressure outside of the molding compound.

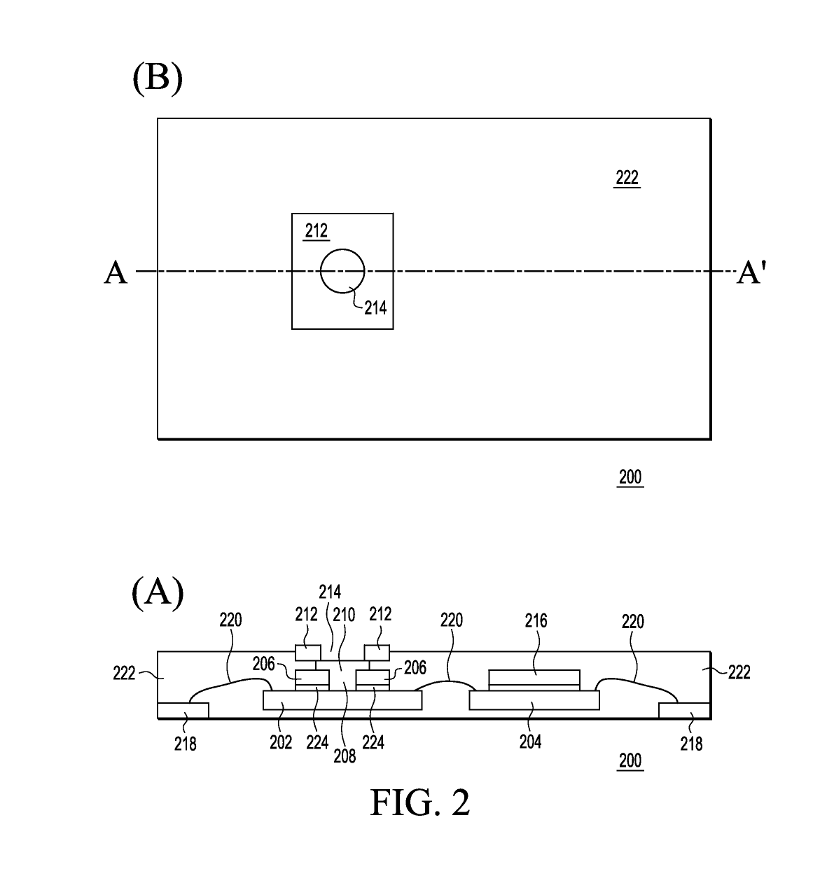

FIGS. 2(A) and 2(B) respectively show a cross-sectional side view and a top plan view of a semiconductor sensor device 200 in accordance with an embodiment of the present invention. The sensor device 200 is in the form of a no-leads type package such as a quad flat no-leads (QFN) package. Note that alternative embodiments are not limited to QFN packages, but can be implemented as other package types, such as (without limitation) ball grid array (BGA) packages, quad flat packages (QFP), or other leaded packages.

The sensor device 200 includes a first, pressure sensing die 202 and a second die 204, which may be an application specific integrated circuit (ASIC). The pressure sensing die (a.k.a. P-cell) 202 is designed to sense ambient atmospheric pressure. The ASIC die 204 is designed to control the operation of and process signals generated by the P-cell 202, and may be a microcontroller or micro-control unit (MCU), as is know in the art. The ASIC die 204 is synonymously referred to herein as MCU 204. Note that, in some embodiments, the ASIC die 204 may implement both the functionality of an MCU and that of one or more other sensors, such as an acceleration sensing G-cell.

Mounted above (in FIG. 2(A)) the pressure sensitive active region of the P-cell 202 using a die attach material 224 is a metal die attach pad 206, which has an opening or hole 208 adjacent to that active region. Note that the die attach material 224 also has a corresponding opening. Depending on the implementation, the die attach material 224 may be any suitable material, such as a die attach adhesive or die attach tape, having an appropriate opening. Filling the hole 208 and covering the P-cell 202 active region is an amount of pressure sensitive gel 210, such as a silicon-based gel. The pressure sensitive gel 210 enables the pressure of the ambient atmosphere to reach the pressure sensitive active region of the P-cell 202, while protecting the P-cell 202 from mechanical damage during packaging and environmental damage (e.g., contamination and/or corrosion) when in use. Examples of suitable pressure sensitive gel 210 are available from Dow Corning Corporation of Midland, Michigan. The gel 210 may be dispensed with a nozzle of a conventional dispensing machine, as is known in the art.

Mounted above the die attach pad 206 and gel 210 is a lid 212 also having a hole 214 adjacent to the hole in the die attach pad 206 and to the P-cell 202 active region. The lid 212 is formed of a durable and stiff material, such as stainless steel, copper, plated metal, or a polymer, so that the P-cell 202 is protected. Depending on the implementation, the lid 212 may have any suitable shape, such as round, square, or rectangular. The hole 214 in the lid 212 enables ambient atmospheric pressure immediately outside the sensor device 200 to reach the gel 210 and the hole 208 in the die attach pad 206, enabling ambient air pressure to reach the active region of the P-cell 202 via the gel 210.

In an analogous manner, mounted above the MCU 204 is a metal die attach pad 216, which includes neither a hole nor a pressure sensitive gel.

The P-cell 202 and MCU 204 are electrically connected to each other and to metal package leads 218 with bond wires 220. In particular, the bond wires 220 are wire bonded between bond pads of the P-cell 202 and corresponding bond pads on the MCU 204 using a suitable, known wire bonding process and suitable, known wire bonding equipment to provide the electrical interconnection between the P-cell 202 and MCU 204. Similarly, the P-cell 202 and MCU 204 are both electrically connected to corresponding package leads 218 by wire bonding between other bond pads on the P-cell 202 and MCU 204 and corresponding package leads 218. The bond wires 220 are formed from a conductive material such as aluminium, gold, or copper, and may be either coated or uncoated. Note that the package leads 218 are vertically offset from the die attach pads 206 and 216.

The entire assembly is encapsulated with a suitable molding compound 222. The molding compound 222 may be a plastic, an epoxy, a silica-filled resin, a ceramic, a halide-free material, the like, or combinations thereof, as is known in the art.

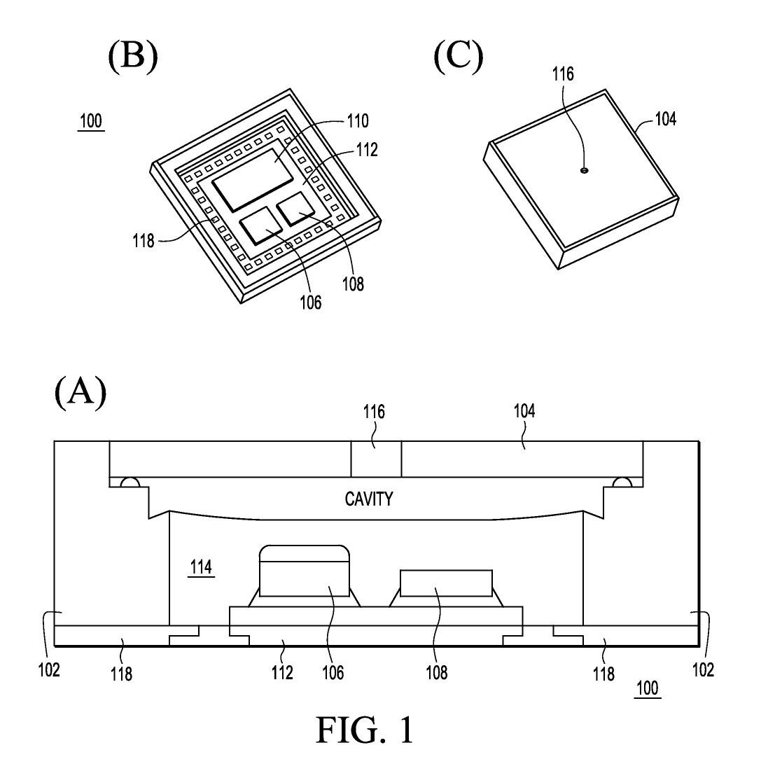

The sensor device 200 is less costly to assemble than comparable sensor devices, like those that are assembled using a pre-molded lead frame, such as the conventional sensor device 100 of FIG. 1, because the sensor device 200 does not use a pre-molded lead frame, can have a smaller lid, and require less pressure sensitive gel.

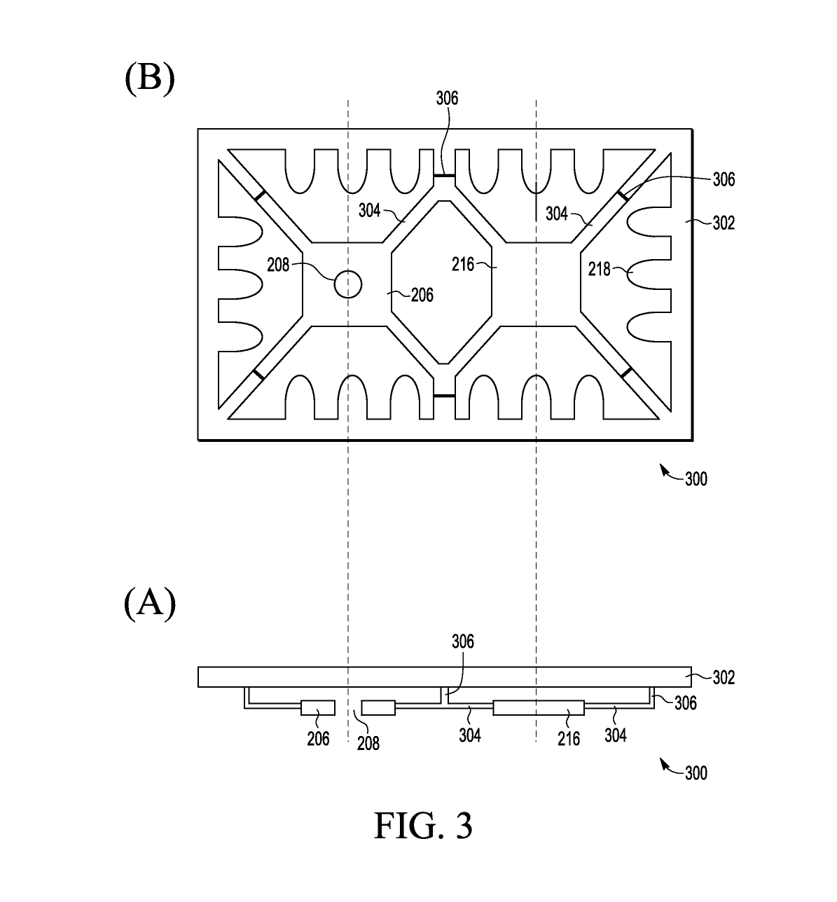

FIGS. 3-8 illustrate one possible process for assembling the sensor device 200 of FIG. 2. In particular, FIGS. 3(A) and 3(B) respectively show a side view and a top plan view of a metal lead frame 300 used to assemble the sensor device 200.

The lead frame 300 has a die attach pad 206 including a hole 208, a die attach pad 216, and a plurality of package leads 218, which all are interconnected by an outer frame 302. The die attach pads 206 and 216 are connected to the outer frame 302 by tie bars 304 having down-set structures 306. As shown in FIG. 3(A), as a result of the down-set structures 306, a lateral plane defined by the die attach pads 206 and 216 is vertically offset from a lateral plane defined by the outer frame 302. The metal lead frame 300 may be formed of copper, an alloy of copper, a copper plated iron/nickel alloy, plated aluminum, or the like, and may be fabricated using any suitable technique, such as etching or stamping.

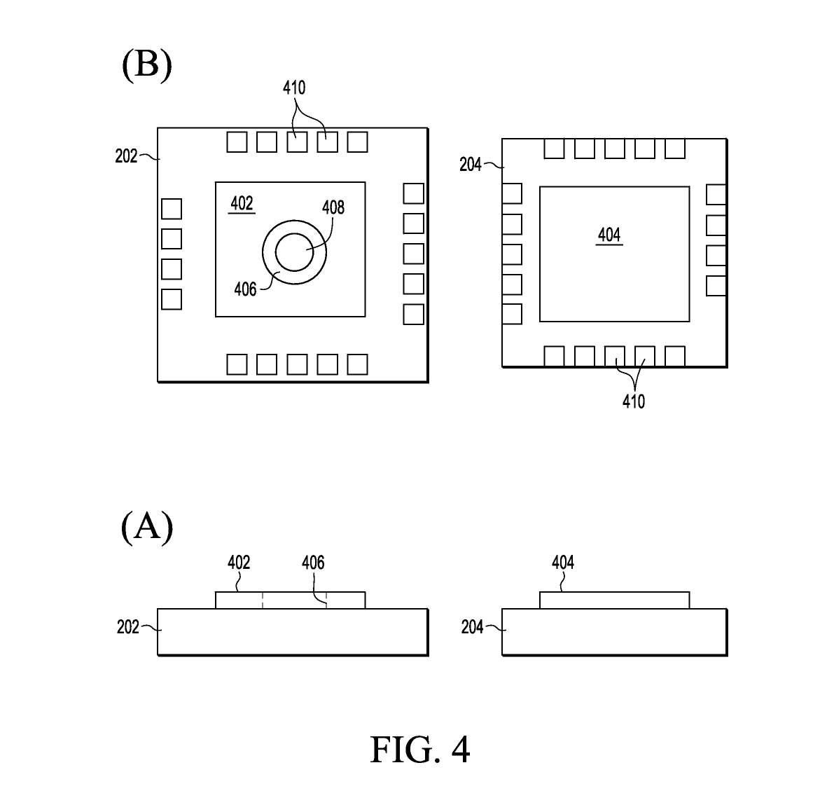

FIGS. 4(A) and 4(B) respectively show a side view and a top plan view of the P-cell 202 and MCU 204 respectively configured with suitable die attach film (DAF) tapes 402 and 404. Note that DAF tape 402 has a hole 406 adjacent to active region 408 of P-cell 202. FIG. 4(B) also shows bond pads 410 on the P-cell 202 and MCU 204.

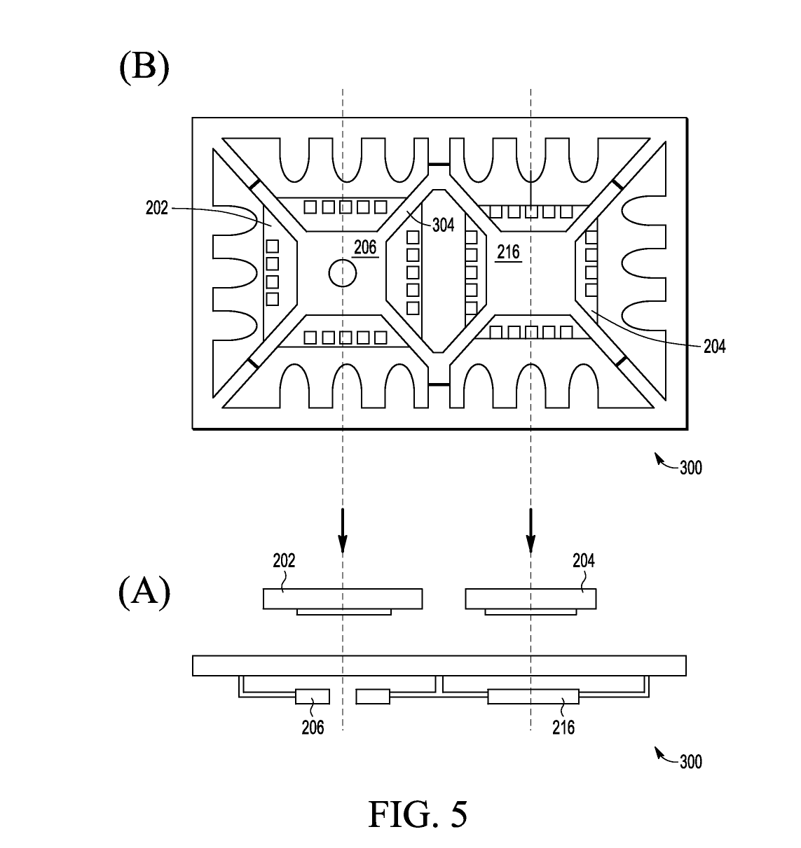

FIGS. 5(A) and 5(B) respectively show a side view and a bottom plan view of DAF tape-configured and flipped-over P-cell 202 and MCU 204 being mounted respectively onto the die attach pads 206 and 216 of the lead frame 300. Note that the hole in the die attach pad 206 leaves the active region of the P-cell 202 exposed, and the relative sizes and configurations of the die attach pads 206 and 216 and tie bars 304 leave the bond pads 410 of the P-cell 202 and MCU 204 exposed.

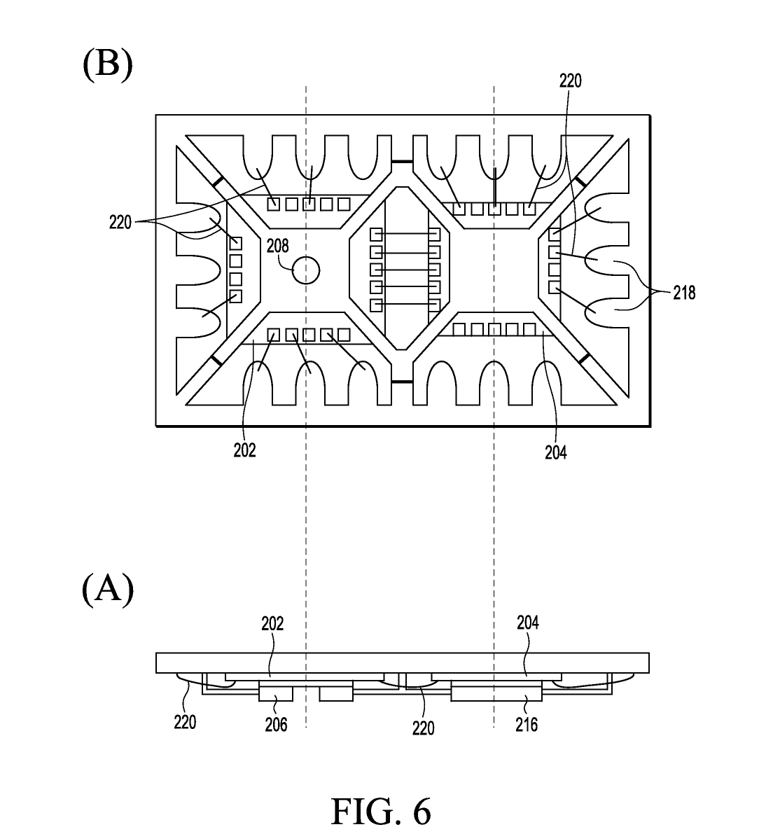

FIGS. 6(A) and 6(B) respectively show a side view and a bottom plan view of the assembly of FIG. 5 after the addition of bond wires 220 that electrically interconnect the P-cell 202 and MCU 204 to each other and to corresponding ones of the package leads 218.

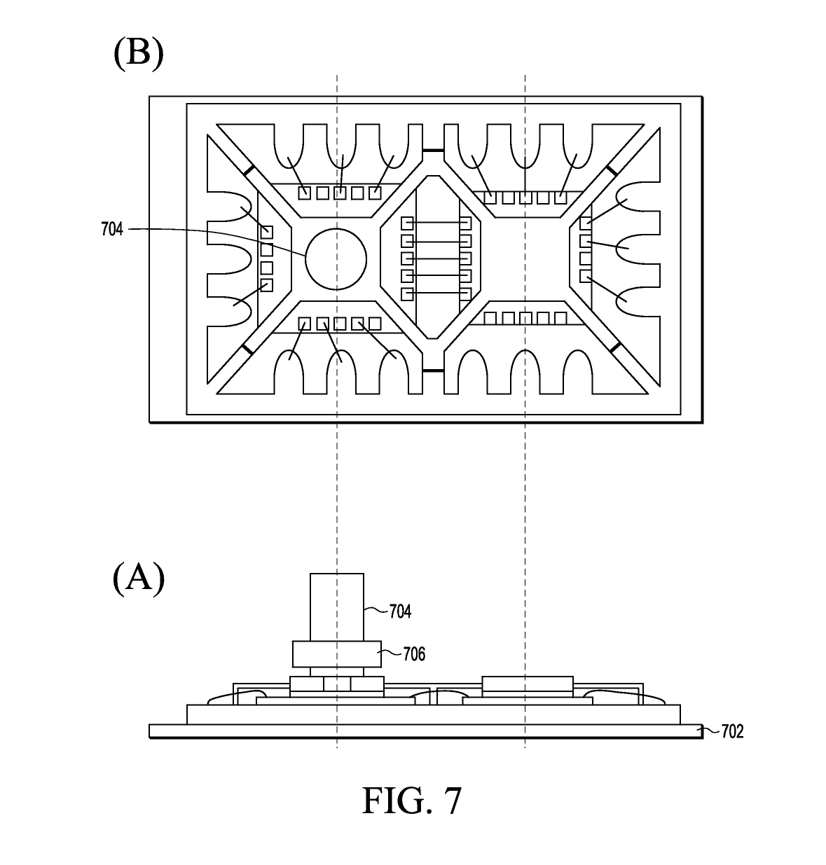

FIGS. 7(A) and 7(B) respectively show a cross-sectional side view and a top plan view of the flipped-over assembly of FIG. 6 after the addition of molding tape 702 and a mold pin 704 having a collar 706.

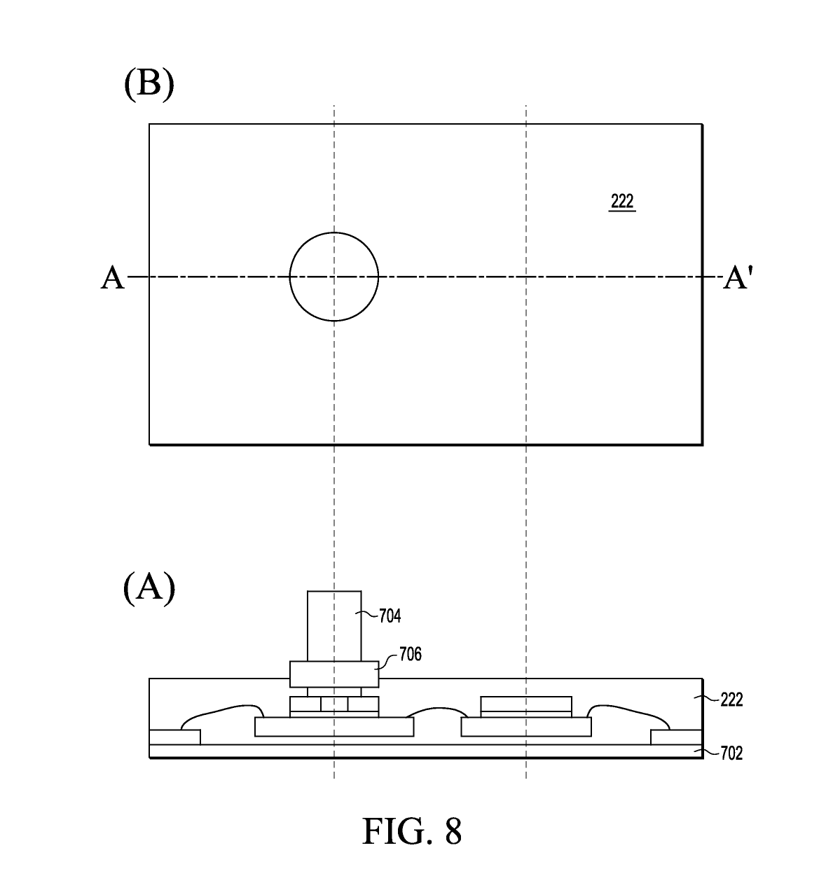

FIGS. 8(A) and 8(B) respectively show a cross-sectional side view and a top plan view of the assembly of FIG. 7 after the addition of molding compound 222, which encapsulates the assembly of FIG. 7. One way of applying the molding compound 222 is using a nozzle of a conventional dispensing machine, as is known in the art. The molding material 222 is typically applied as a liquid polymer, which is then heated to form a solid by curing in a UV or ambient atmosphere. The molding material 222 also can be a solid that is heated to form a liquid for application and then cooled back to a solid. In alternative embodiments, other encapsulating processes may be used. Subsequently, an oven is used to cure the molding material 222 to complete the cross linking of the polymer.

After encapsulation, the molding tape 702 and mold pin 704 are removed, a lid 212 is installed, and pressure sensitive gel 210 of FIG. 2 is applied to active region 408 of the P-cell 202 through the hole 214 in the lid 212 to fill the hole 208 in the die attach pad 206 and the hole 406 in the DAF tape 402. Note that the collar 706 of the mold pin 704 has the same outer diameter as the lid 212 so that the lid 212 will fit snugly within the seat formed in the molding compound 222 by the collar 706. Note further that, in alternative assembly processes, the gel 210 can be applied before the lid 212 is installed.

Although not depicted in the drawings, in real-world manufacturing, a two-dimensional array of the sensor devices 200 is assembled in a multi-device lead frame that includes of a two-dimensional array of the lead frames 300 of FIG. 3. The simultaneously formed sensor devices are then separated, e.g., in a singulation process involving a saw or laser, to form individual instances of sensor device 200. Note that the singulation process removes the material forming outer frame 302 of FIG. 3, resulting in physically and electrically isolated package leads 218.

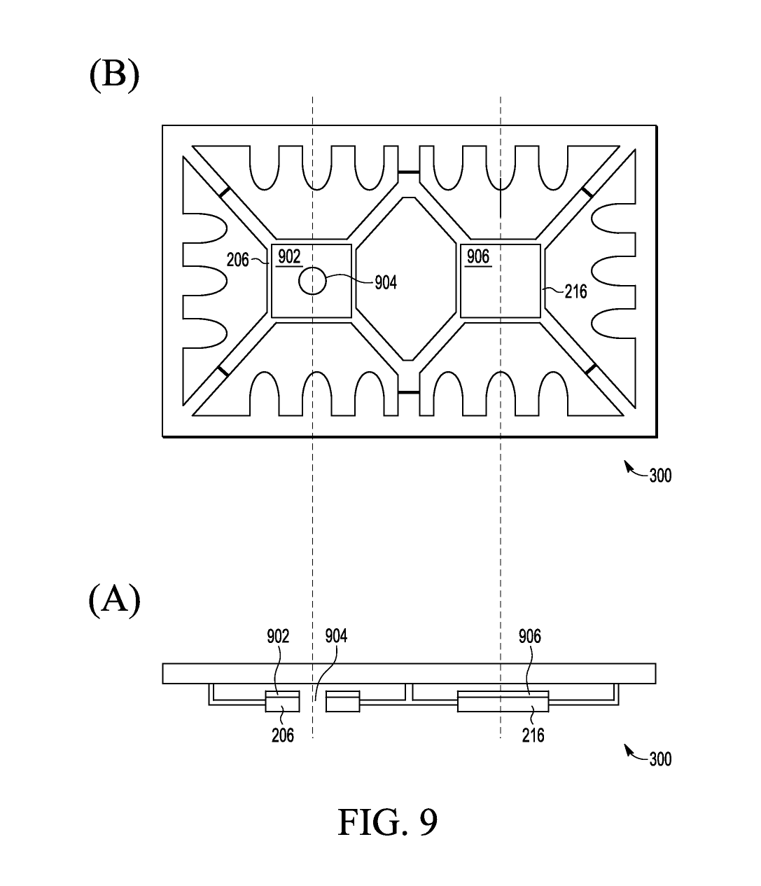

In the assembly technique illustrated in FIGS. 3-8, the P-cell 202 and MCU 204 are respectively mounted to the die attach pads 206 and 216 by first applying DAF tape to the dies and then mounting the DAF tape-configured dies to the die attach pads. FIG. 9 illustrates an alternative technique in which the DAF tape is first applied to the die attach pads such that the dies are then mounted to the DAF tape-configured die attach pads. In particular, FIGS. 9(A) and 9(B) respectively show a side view and a top plan view of lead frame 300 with DAF tape 902 having hole 904 and DAF tape 906 respectively applied to die attach pads 206 and 216.

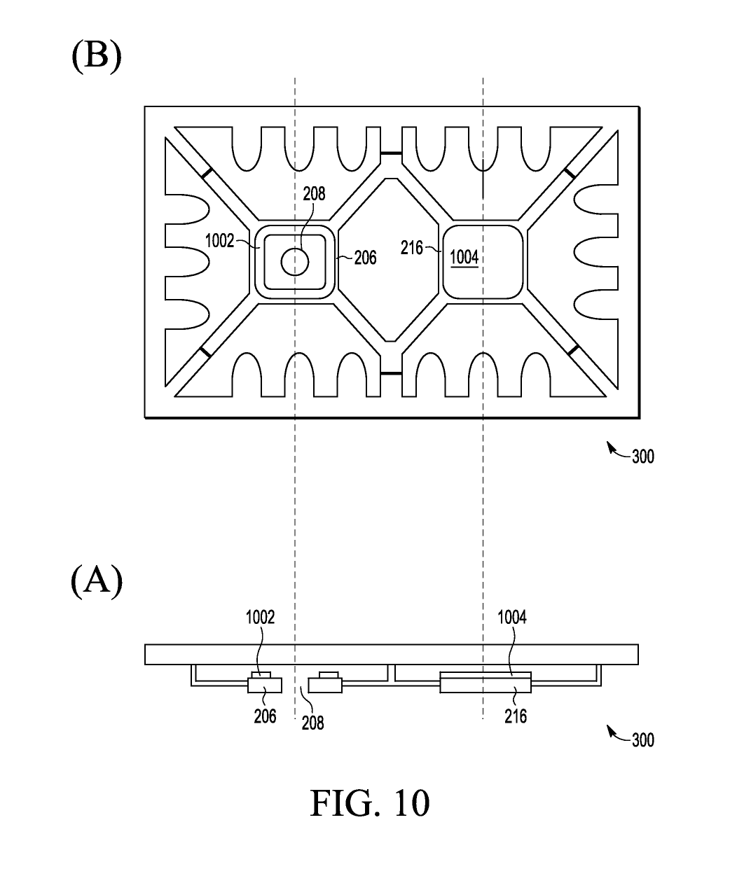

According to other assembly techniques, epoxy is used to connect the dies to the die attach pads instead of DAF tape. FIGS. 10(A) and 10(B) respectively show a side view and a top plan view of the lead frame 300 with epoxy 1002 and 1004 respectively applied to the die attach pads 206 and 216. Note that the epoxy 1002 is applied in a ring around the hole 208 in the die attach pad 206. In alternative assembly techniques, the epoxy can be applied to the dies first rather than to the die attach pads.

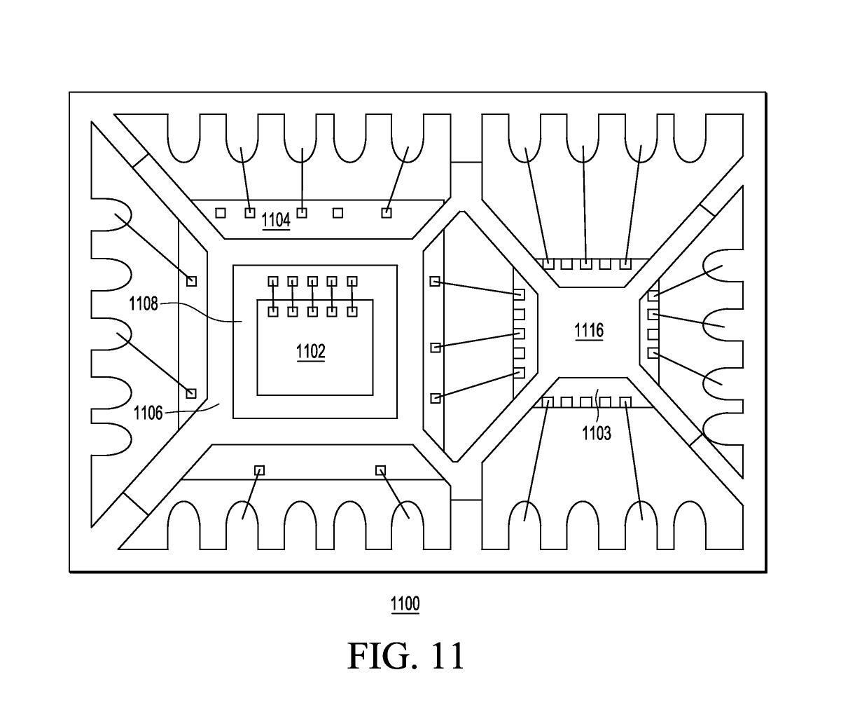

FIG. 11 shows a bottom plan view of a die/lead frame sub-assembly for a sensor device 1100 according to another embodiment of the disclosure. The sub-assembly of FIG. 11 corresponds to the analogous stage in the manufacturing process of sensor device 200 shown in FIG. 6. Unlike sensor device 200 which has two dies (i.e., P-cell 202 and MCU 204), sensor device 1100 has three dies (i.e., P-cell 1102, MCU 1104, and G-cell 1103), where the P-cell 1102 is mounted to MCU 1104, which is in turn mounted to die attach pad 1106, while G-cell 1103 is mounted to the other die attach pad 1116. The G-cell 1103 is an acceleration sensing die designed to sense gravity or acceleration in one, two, or all three axes, depending on the particular implementation. Unlike the die attach pad 206 of the sensor device 200, which has a relatively small (e.g., circular) hole 208, the die attach pad 1106 has a larger (e.g., rectangular) opening 1108 in order to accommodate the periphery of the P-cell 1102. Note that the P-cell 1102 can be mounted and wire bonded to the MCU 1104 before the MCU 1104 is mounted to the die attach pad 1106.

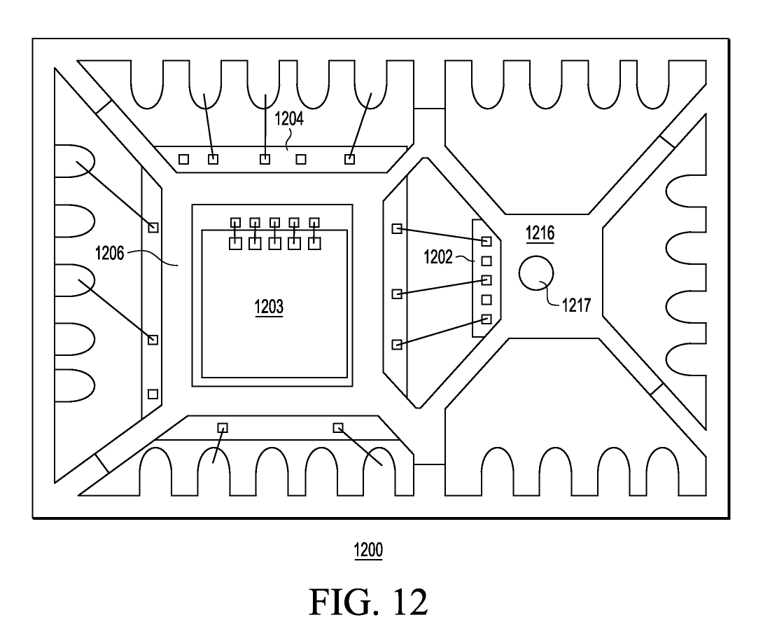

FIG. 12 shows a bottom plan view of a die/lead frame sub-assembly for a sensor device 1200 according to yet another embodiment of the present invention. The sub-assembly of FIG. 12 corresponds to the analogous assembly stage represented in FIGS. 6 and 11. Unlike the sensor device 1100 of FIG. 11, which has a P-cell 1102 mounted to an MCU 1104, the sensor device 1200 has a G-cell 1203 mounted to an MCU 1204, which is in turn mounted to a die attach pad 1206, while a P-cell 1202 is mounted to the other die attach pad 1216, which has a hole 1217 to expose the P-cell's active region.

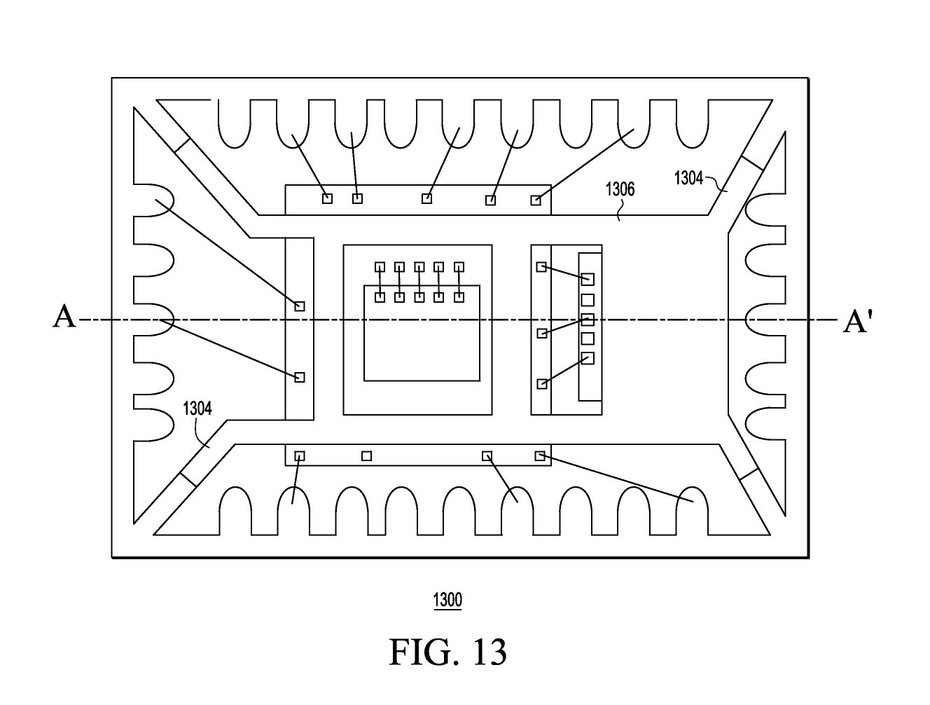

FIG. 13 shows a bottom plan view of a die/lead frame sub-assembly for a sensor device 1300 according to yet another embodiment of the present invention. The sub-assembly of FIG. 13 corresponds to the analogous manufacturing stage represented in FIGS. 6, 11, and 12. Unlike the lead frames of those other embodiments, each of which has six different tie bars to support two different die attach pads, the lead frame of FIG. 13 has only four tie bars 1304 that supports a one-piece, two-die die attach structure 1306, where, analogous to sensor device 1100 of FIG. 11, sensor device 1300 has a P-cell/MCU sub-assembly mounted to one die attach region of structure 1306 and a G-cell mounted to the structure's other die attach region.

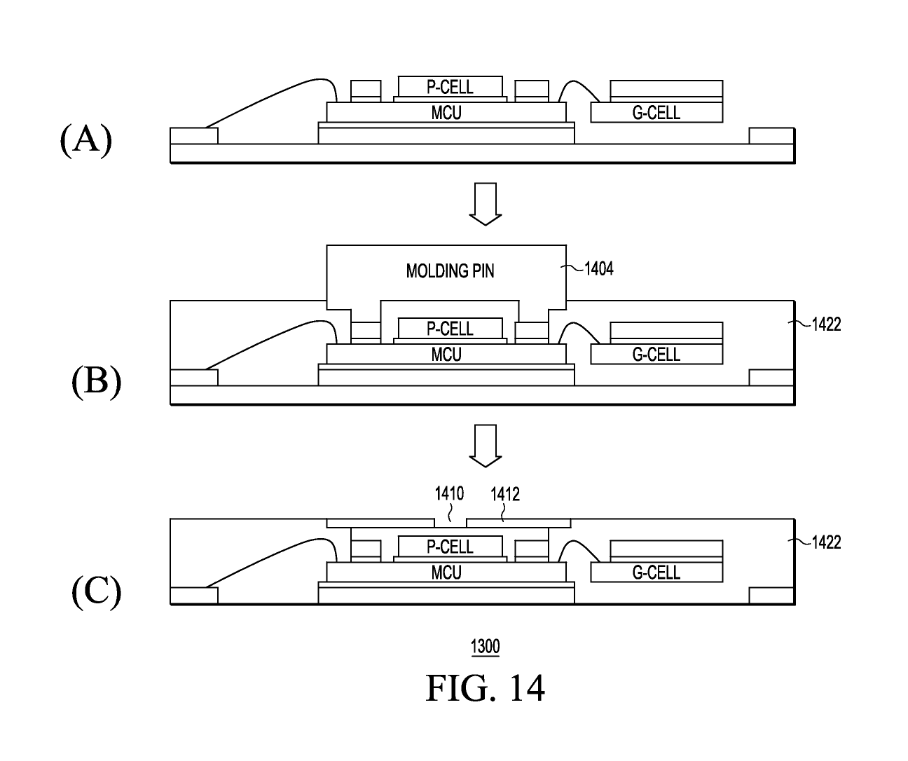

FIGS. 14(A)-14(C) illustrate some of the steps in completing the assembly process for sensor device 1300 of FIG. 13. In particular, FIG. 14(A) shows a cross-sectional side view of the die/lead frame sub-assembly of FIG. 13 configured with molding tape 1402. FIG. 14(B) shows a cross-sectional side view of the sub-assembly of FIG. 14(A) after molding compound 1422 has been applied with a mold pin 1404 in place. FIG. 14(C) shows a cross-sectional side view of the sub-assembly of FIG. 14(B) after molding tape 1402 and mold pin 1404 have been removed; pressure sensitive gel 1410 has been applied to fill the hole in the molding compound 1422 created by the mold pin; and a lid 1412 has been attached. Note that FIG. 14(C) illustrates the final assembled version of sensor device 1300.

As used herein, the term “mounted to” as in “a first die mounted to a die attach pad” covers situations in which the first die is mounted directly to the die attach pad with no other intervening dies (as in the mounting of P-cell 202 to die attach pad 206 in FIG. 2) as well as situations in which the first die is directly mounted to another die, which is itself mounted directly to the die attach pad (as in the mounting of P-cell 1102 to die attach pad 1106 in FIG. 11). Note that “mounted to” also covers situations in which there are two or more intervening dies between the first die and the die attach pad.

MCUs, P-cells, and G-cells are well-known components of semiconductor devices and thus detailed descriptions thereof are not necessary for a complete understanding of the disclosure.

Although FIGS. 11 and 13 shows sensor devices having a P-cell and a G-cell, those skilled in the art will understand that, in alternative embodiments, the G-cell and its corresponding die attaching pad may be omitted. Such a sensor device would have the P-cell mounted to the MCU, and the MCU mounted to the only die attach pad of the lead frame, where an opening in that die attach pad exposes or otherwise provides access to the P-cell's active region.

Although FIGS. 11-14 show embodiments in which a sensor die is mounted to the MCU die with the electrical interconnection provided by wire bonding, those skilled in the art will understand that the electrical interconnection between such dies can, alternatively or additionally, be provided by appropriate flip-chip assembly techniques. According to these techniques, two semiconductor dies are electrically interconnected through flip-chip bumps attached to one of the semiconductor dies. The flip-chip bumps may include solder bumps, gold balls, molded studs, or combinations thereof. The bumps may be formed or placed on a semiconductor die using known techniques such as evaporation, electroplating, printing, jetting, stud bumping, and direct placement. The semiconductor die is flipped, and the bumps are aligned with corresponding contact pads of the other die.

Although the disclosure has been described in the context of embodiments having a pressure sensing P-cell die and a separate MCU die, those skilled in the art will understand that the invention can also be implemented in an embodiment in which the pressure sensing functionality and the MCU functionality are implemented in a single, multi-function die. Such an embodiment may be manufactured using a lead frame having only a single die attach pad with a suitable hole to expose the active pressure sensing region of the multi-function die.

By now it should be appreciated that there has been provided an improved packaged semiconductor sensor device and a method of forming the packaged semiconductor sensor device. Circuit details are not disclosed because knowledge thereof is not required for a complete understanding of the invention.

Although the invention has been described using relative terms such as “front,” “back,” “top,” “bottom,” “over,” “above,” “under” and the like in the description and in the claims, such terms are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the disclosure is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non enabled embodiments and embodiments that correspond to non statutory subject matter are explicitly disclaimed even if they fall within the scope of the claims.

1. A method for manufacturing a semiconductor sensor device, the method comprising:
(a) mounting one or more dies including a pressure sensing die to at least a first die attach pad of a lead frame further comprising an outer frame with a plurality of attached leads, wherein:
the first die attach pad is connected to the outer frame by a plurality of tie bars;
the lead frame defines a first lateral plane;
the at least the first die attach pad defines a second lateral plane vertically offset from the first lateral plane;
the pressure sensing die is mounted to the first die attach pad; and
the first die attach pad has an opening that provides access to an active region of the pressure sensing die;
(b) wire bonding the one or more dies to corresponding leads of the lead frame;
(c) encapsulating the one or more wire bonded dies, the at least the first die attach pad, and the corresponding wire bond pads in a molding compound, while preserving the access to the active region of the pressure sensing die via the opening in the first die attach pad;
(d) applying pressure sensitive gel through the opening in the first die attach pad to cover the active region of the pressure sensing die; and
(e) separating the sensor device from one or more other instances of the sensor device, wherein the multiple wire bond pads become detached from the outer frame of the lead frame.

2. The method of claim 1, wherein each tie bar has a down-set structure that vertically offsets the second lateral plane from the first lateral plane.

3. The method of claim 1, wherein step (d) further comprises mounting a lid over the pressure sensing die, wherein the lid has a hole that exposes the gel-covered active region of the pressure sensing die to ambient atmospheric pressure outside the sensor device.

4. The method of claim 1, wherein:
the one or more dies further comprise an ASIC die; and
step (a) further comprises mounting the ASIC die to the at least the first die attach pad; and
step (b) further comprises electrically connecting the pressure sensing die to the ASIC die.

5. The method of claim 4, wherein:
the ASIC die is mounted to a second die attach pad of the lead frame; and
the ASIC die is electrically connected to the pressure sensing die via bond wires.

6. The method of claim 5, wherein the one or more dies further comprises a second sensor die mounted to the ASIC die within an opening in the second die attach pad.

7. The method of claim 4, wherein:
the pressure sensing die is mounted to the ASIC die; and
the ASIC die is mounted to the first die attach pad.

8. The method of claim 7, wherein the pressure sensing die is electrically connected to the ASIC die via bond wires.

9. The method of claim 7, wherein:
the one or more dies further comprises a second sensor die mounted to a second die attach pad of the lead frame; and
the second sensor die is electrically connected to the ASIC die via bond wires.

10. The method of claim 1, wherein the access to the active region of the pressure sensing die is preserved in step (c) by using a mold pin to prevent the molding compound from entering the opening in the first die attach pad.

11. The semiconductor sensor device assembled using the method of claim 1.

12. The semiconductor sensor device assembled using the method of claim 2.

13. The semiconductor sensor device assembled using the method of claim 3.

14. The semiconductor sensor device assembled using the method of claim 4.

15. The semiconductor sensor device assembled using the method of claim 10.

16. A semiconductor sensor device, comprising:
a first die attach pad having an opening;
one or more dies including a pressure sensing die mounted to the first die attach pad;
a plurality of leads that surround the first die attach pad and lie in a first lateral plane;
bond wires electrically connecting the one or more dies to corresponding ones of the leads;
a plurality of tie bars connected to the first die attach pad;
pressure sensitive gel covering an active region of the pressure sensing die; and
molding compound encapsulating the first die attach pad, the one or more dies, the bond wires, the tie bars, and at least portions of the leads, wherein,
the first die attach pad lies in a second lateral plane vertically offset from the first lateral plane;
the opening in the first die attach pad provides access to the active region of the pressure sensing die; and
the molding compound has a hole corresponding to the opening in the first die attach pad, wherein the hole exposes the gel covered active region of the pressure sensing die to ambient atmospheric pressure outside of the molding compound.

17. The sensor device of claim 16, further comprising a lid mounted over the pressure sensing die, wherein the lid has a hole corresponding to the opening in the first die attach pad that exposes the gel covered active region of the pressure sensing die to the ambient atmospheric pressure outside the sensor device.

18. The sensor device of claim 16, further comprising a second sensor die mounted to a second die attach pad.

19. The sensor device of claim 18, wherein the second sensor die is an acceleration sensing die.
